(19) United States
(12) Patent Application Publication
(10) Pub. No.: US 2005/0011548 A1
(43) Pub. Date: Jan. 20, 2005

(54) Photovoltaic converter

(75) Inventors: Tomonori Nagashima, Susono-shi (JP); Kazuyoshi Kawaguchi, Nagoya-shi (JP)

Correspondence Address: Finnegan, Henderson, Farabow,;Garrett & Dunner, L.L.P, 1300 I Street, N.W., Washington, DC, 20005-3315, US

(73) Assignee: Toyota Jidosha Kabushiki Kaisha

(21) Appl. No.: 10/867,012

(22) Filed: Jun. 15, 2004

(30) Foreign Application Priority Data
Jun. 24, 2003 (JP) 2003-180029

(51) Int. Cl. H02N 6/00; H01L 25/00; H01L 31/00

(52) U.S. Cl. 136/243

(57) ABSTRACT

A photovoltaic converter, maintaining the function of a protective film, simultaneously reducing the reflection loss and carrier recombination loss, and raising the power generation efficiency, formed on a semiconductor substrate and provided on its light receiving surface with a silicon nitride film as a protective film/antireflection film, wherein a content of hydrogen or a halogen is increased and a ratio of Si content/N content is increased at a boundary region of the silicon nitride film with the semiconductor substrate compared with other portions so as to maintain a refractive index at the boundary region equal to the other portions.

### BACKGROUND OF THE INVENTION

1. Field of the Invention

The present invention relates to a photovoltaic converter formed on a semiconductor substrate and provided on its light receiving surface with a silicon nitride film etc. as a protective film/antireflection film, more particularly relates to a photovoltaic converter reduced in reflection loss and carrier recombination loss.

2. Description of the Related Art

In recent years, as devices for directly obtaining electrical energy from heat sources, attention is being focused on thermophotovoltaics (TPV). The principle is to heat a light emitter by a heat source to cause the emission of radiant light from the light emitter and to project this radiant light on a photovoltaic converter (PV cell) to obtain electrical energy. As the heat source, the exhaust heat from various types of plants, boilers, heaters, etc. or the heat of combustion of fossil fuels is used.

TPV uses radiant light obtained in particular from a light emitter of a temperature of 1000 to 1700° C. The obtained radiant light is infrared light of a wavelength range of 1.4 to 1.7 μm. To convert this to electric power, it is necessary to use a photovoltaic converter fabricated from a semiconductor material with a small band gap (Eg). The typical semiconductor material Si can only convert light of a wavelength range of not more than 1.1 μm to electric power.

As a photovoltaic converter for TPV, one with a band gap of 0.5 to 0.7 ev is suitable. As representative materials, there are GaSb (gallium antimony, Eg=0.72 ev), InGaAs (indium gallium arsenic, Eg=0.60 to 1.0 ev), Ge (germanium, Eg=0.66 ev), etc.

To raise the power generation efficiency of a photovoltaic converter, it is important to reduce the reflection loss due to reflection at the light receiving surface and reduce the carrier recombination loss due to recombination of the generated positive and negative carriers. As antireflection films for this purpose, a plurality of SiO₂, MgF₂, TiO₂, ZnS, and other optical thin films are used stacked together by sputtering or vapor deposition. As the positional relationships of the layers, the large refraction index TiO₂ or ZnS is arranged at the substrate side while the small refraction index SiO₂ or MgF₂ is arranged at the outer surface side. However, if directly forming a thin film of TiO₂ or ZnS on the surface of a Ge or other semiconductor substrate, a large amount of defects will remain at the surface of the semiconductor substrate or elements serving as sources of contamination will diffuse at the surface of the semiconductor substrate to cause new defects. As a result, the concentration of defects becoming carrier recombination sites will become higher near the light receiving surface, the carrier recombination loss will increase, and the power generation efficiency will fall.

As a measure against this, for example, Japanese Unexamined Patent Publication (Kokai) No. 2001-284616 proposes provision of a thin film reducing the defects at the light receiving surface side of the substrate. As the material of this thin film, a silicon nitride (SiNx), silicon dioxide (SiO₂), etc. is used to form a film by plasma CVD or thermal oxidation. By providing these thin films, the dangling bonds of the substrate surface are reduced and elements serving as sources of contamination are prevented from diffusion to the substrate surface.

The above related art suffered from the following problems 1 and 2.

<Problem 1>

As one effect of reduction of defects by a silicon nitride (SiNx) film, there is known the action of the hydrogen (H) contained by the film bonding with the dangling bonds of the surface of the semiconductor substrate as shown in FIG. 11 (in the figure, the case of Ge substrate shown). Therefore, if providing a silicon nitride film with a large content of hydrogen, the effect of reduction of defects due to the reduction of the dangling bonds becomes greater.

However, if a silicon nitride film contains a large content of hydrogen, its function as a protective film drops. To obtain a defect reducing effect while maintaining the function as a protective film, it may be considered to increase the hydrogen content only at the boundary region with the substrate. If the hydrogen content becomes greater, however, the refractive index of the silicon nitride film becomes smaller, so there is the problem that the refractive index would differ between the boundary region with the large hydrogen content and the other locations and therefore the antireflection effect would end up falling.

<Problem 2>

Normally, the refractive index of a silicon nitride film is about 1.8 to 2.1. This refractive index is suitable as an antireflection film provided at the surface of an Si substrate or Ge substrate. When forming an antireflection film having a stacked structure of two layers, three layers, or more layers able to further reduce the reflection loss, the bottommost layer film provided at the substrate surface must have a refractive index larger than the thin films used for the higher stacked structures. Therefore, the optimal refractive index is about 2.4 to 2.8. Use of silicon nitride as the bottommost layer film is therefore not possible.

Accordingly, as shown in FIG. 12, at the light receiving surface (top surface in the figure) of the photovoltaic converter E1, normally TiO₂, ZnS, or another high refractive index film R1 is used as the bottommost layer film and an SiNx film (medium refractive index film R2) and SiO₂ film (low refractive index film R3) are successively formed on top of this. The photovoltaic converter E1 is formed on a p-type semiconductor substrate 10. At the side end of the back surface (bottom end of the figure) of the semiconductor substrate 10, a p+ layer 18 and n+ layer 20 are formed by diffusion as carrier polarization layers. These are connected to positive and negative external output electrodes 24 and 26. The back surface other than the connection positions of the carrier polarization layers 18 and 20 and output electrodes 24 and 26 is covered by a protective film (insulating film) 28. However, the TiO₂, ZnS, or other film used as the bottommost layer film R1 has a small effect of reduction of the dangling bonds of the surface of the semiconductor substrate as compared with an SiNx film R2 or SiO₂ film R3, so an effect of reduction of the carrier recombination loss due to the reduction of the defects cannot be obtained.

Further, as with the photovoltaic converter E2 shown in FIG. 13, it has been proposed to arrange the low refractive index films (SiO₂, MgF₂, etc.) R3 at the outer surface side and the high refractive index film (TiO₂, ZnS, etc.) R1 at the substrate side and further interpose a silicon nitride film R2 as the bottommost layer film between the high refractive index film and substrate. However, the bottommost layer film constituted by the silicon nitride film R2 in the stacked structure has a refractive index lower than the high refractive index film R1 directly above it, so there is the problem of a drop in the antireflection effect.

In the final analysis, in the related art, it was not possible to maintain the function of the protective film, simultaneously reduce the reflection loss and carrier recombination loss, and raise the power generation rate.

### SUMMARY OF THE INVENTION

An object of the present invention is to provide a photovoltaic converter which maintains the function of the protective film, simultaneously reduces the reflection loss and carrier recombination loss, and raises the power generation rate.

To achieve the above object, according to a first embodiment of a first aspect of the invention, there is provided a photovoltaic converter formed on a semiconductor substrate and provided on its light receiving surface with a silicon nitride film as a protective film/antireflection film, wherein a content of hydrogen or a halogen is increased and a ratio of Si content/N content is increased at a boundary region of the silicon nitride film with the semiconductor substrate compared with other portions so as to maintain a refractive index at the boundary region equal to the other portions.

Further, according a second embodiment of the first aspect of the invention, there is provided a photovoltaic converter formed on a semiconductor substrate and provided on its light receiving surface with a silicon nitride film as a protective film/antireflection film, wherein an Si—H₂/Si—H bond ratio is increased and a content of hydrogen or a halogen is decreased or a ratio of Si content/N content is increased at a boundary region of the silicon nitride film with the semiconductor substrate compared with other portions so as to maintain a refractive index at the boundary region equal to the other portions.

Further, according a third embodiment of the first aspect of the invention, there is provided a photovoltaic converter formed on a semiconductor substrate and provided on its light receiving surface with a silicon nitride film as a protective film/antireflection film, wherein an N—H/Si—H bond ratio is increased and a content of hydrogen or a halogen is reduced or a ratio of Si content/N content is increased at a boundary region of the silicon nitride film with the semiconductor substrate compared with other portions so as to maintain a refractive index at the boundary region equal to the other portions.

Preferably, in the first, second and third embodiments of the first aspect of the invention, the increase and decrease are a step-wise or continuous gradual increase and gradual decrease from a silicon nitride film body side to the semiconductor substrate side.

Further, according a fourth embodiment of the first aspect of the invention, there is provided a photovoltaic converter formed on a semiconductor substrate and provided on its light receiving surface with an antireflection film comprised of a material other than silicon nitride, wherein a silicon nitride film of a composition and bond form corresponding to a boundary region defined in any one of the first, second and third embodiments is interposed between the antireflection film and semiconductor substrate.

On the other hand, according to a first embodiment of a second aspect of the invention, there is provided a photovoltaic converter formed on a semiconductor substrate and provided on its light receiving surface with a silicon nitride film as a protective film/antireflection film, wherein the silicon nitride film is comprised of a plurality of component layers stacked together and the refractive indices of the component layers increase from the outer surface side to the substrate side.

At this time, it is possible to adjust the refractive indices of the component layers by one of the content of hydrogen or a halogen, the ratio of the Si content/N content, and the N—H/Si—H bond ratio.

According to the second embodiment of the second aspect of the invention, there is provided a photovoltaic converter interposing a region corresponding to the boundary region defined in any one of the first, second, and third embodiments of the first aspect of the invention inside the component layer adjoining the semiconductor substrate among the component layers of the silicon nitride film.

### BRIEF DESCRIPTION OF THE DRAWINGS

These and other objects and features of the present invention will become clearer from the following description of the preferred embodiments given with reference to the attached drawings, wherein:

FIGS. 1A to 1C show an example of a photovoltaic converter according to a first embodiment of a first aspect of the invention, wherein FIG. 1A is a cross-sectional view of a photovoltaic converter, FIG. 1B is a graph of the profile of concentration of hydrogen or a halogen along the line A-B of FIG. 1A, and FIG. 1C is a graph of the profile of the Si concentration/N concentration ratio along the line A-B of FIG. 1A;

FIG. 2A is a graph of the profile of step-wise change of the content of hydrogen or a halogen, and FIG. 2B a graph of the profile of step-wise change of the ratio of Si content/N content in the photovoltaic converter of FIG. 1A;

FIG. 3A is a graph of the profile of continuous change of the content of hydrogen or a halogen, and FIG. 3B a profile of continuous change of the ratio of Si content/N content in the photovoltaic converter of FIG. 1A;

FIGS. 4A and 4B are graphs of features of the boundary region of a photovoltaic converter according to a second embodiment of the first aspect of the invention, wherein FIG. 4A is a graph of the profile of the Si—H₂/Si—H bond ratio and FIG. 4B is a graph of the profile of content of hydrogen or a halogen;

FIGS. 5A and 5B are graphs of features of the boundary region of a photovoltaic converter according to a third embodiment of the first aspect of the invention, wherein FIG. 5A is a graph of the profile of the N—H/Si—H bond ratio and FIG. 5B is a graph of the profile of content of hydrogen or a halogen;

FIG. 6 is a cross-sectional view of a photovoltaic converter according to a fourth embodiment of the first aspect of the invention;

FIG. 7A is a cross-sectional view of a photovoltaic converter according to a first embodiment of the second aspect of the invention, FIG. 7B shows the profile of content of hydrogen or a halogen, FIG. 7C shows the profile of the refractive index, FIG. 7D shows the profile of ratio of Si content/N content, and FIG. 7E shows the profile of the N—H/Si—H bond ratio;

FIG. 8 is a cross-sectional view of a photovoltaic converter according to a second embodiment of the second aspect of the invention;

FIG. 9 is a view of an example of the configuration of a plasma CVD system for forming a silicon nitride film of the present invention;

FIG. 10 is a view of an example of the configuration of an ECR plasma CVD system for forming a silicon nitride film of the present invention;

FIG. 11 is a schematic view of the state of bonding between the silicon nitride film and dangling bonds at the surface of a Ge substrate;

FIG. 12 is a cross-sectional view of the configuration of an antireflection film in a photovoltaic converter of the related art; and

FIG. 13 is cross-sectional view of another configuration of an antireflection film in a photovoltaic converter of the related art.

### DESCRIPTION OF THE PREFERRED EMBODIMENTS

Preferred embodiments of the present invention will be described in detail below while referring to the attached figures.

According to the first aspect of the invention, as the means X for reducing carrier recombination loss at the boundary region of the silicon nitride film with the semiconductor substrate, the ingredient or bond form having the action of reducing the dangling bonds on the surface of the semiconductor substrate is increased and, simultaneously, as the means Y for reducing the reflection loss, the ingredient or bond form for canceling out the drop in refractive index due to the means X is increased or decreased, so as to maintain the refractive index constant as a silicon nitride film as a whole. Therefore, it is possible to simultaneously reduce the reflection loss and carrier recombination loss and raise the power generation efficiency. Since only the boundary region is involved in application of the means X and Y, the function as a protective film is maintained by other portions of the silicon nitride film.

The first aspect of the invention achieves similar actions and effects by the following combination of the means X and means Y with respect to the boundary region by the first, second, and third embodiments.

<First Embodiment>

Means X

Increasing the content of hydrogen or a halogen. Due to this, defects arising due to dangling bonds of the surface of the semiconductor substrate are reduced and the carrier recombination loss is reduced.

However, if raising the content of hydrogen or a halogen, the refractive index of the silicon nitride film will fall. That is, the bottommost layer part of the silicon nitride film constituted by the boundary region will have a lower refractive index than the region near the outer surface, so the antireflection effect will drop.

Means Y

Increasing the ratio of the Si content/N content. Due to this, the refractive index of the silicon nitride film is increased, the drop in refractive index due to the increase in content of hydrogen or a halogen is cancelled out to make the refractive index at the boundary region equal to the refractive index of the other portions, the refractive index is kept constant at the silicon nitride film as a whole, and the antireflection effect is improved to reduce the reflection loss.

<Second Embodiment>

Means X

Increasing the S₁—H₂/Si—H bond ratio. Due to this, the defects due to the dangling bonds of the surface of the semiconductor substrate are reduced and the carrier recombination loss is reduced.

However, if increasing the S₁—H₂/Si—H bond ratio, the refractive index of the silicon nitride film falls. That is, the bottommost layer part in the silicon nitride film constituted by the boundary region becomes lower in refractive index than the region near the outer surface, so the antireflection effect falls.

Means Y

Decreasing the content of hydrogen or a halogen or increasing the ratio of the Si content/N content. Due to this, the refractive index of the silicon nitride film is increased, the drop in refractive index due to the increase in S₁—H₂/Si—H bond ratio is cancelled out to make the refractive index in the boundary region the same as the refractive index at the other portions, the refractive index is kept constant at the silicon nitride film as a whole, and the antireflection effect is improved to reduce the reflection loss.

<Third Embodiment>

Means X

Increasing the N—H/Si—H bond ratio. Due to this, the defects due to the dangling bonds of the surface of the semiconductor substrate are reduced and the carrier recombination loss is reduced.

However, if increasing the N—H/Si—H bond ratio, the refractive index of the silicon nitride film falls. That is, the bottommost layer part in the silicon nitride film constituted by the boundary region becomes lower in refractive index than the region near the outer surface, so the antireflection effect falls.

Means Y

Decreasing the content of hydrogen or a halogen or increasing the ratio of the Si content/N content. Due to this, the refractive index of the silicon nitride film is increased, the drop in refractive index due to the increase in N—H/Si—H bond ratio is cancelled out to make the refractive index in the boundary region the same as the refractive index at the other portions, the refractive index is kept constant at the silicon nitride film as a whole, and the antireflection effect is improved to reduce the reflection loss.

Next, according to the second aspect of the invention, by positively increasing the refractive index of the silicon nitride film and using this as a high refractive index film instead of the conventional TiO₂, ZnS, etc., a high antireflection effect and substrate surface defect reducing effect are simultaneously achieved. That is, a silicon nitride film of the structure of a plurality of component layers stacked together is used so that the refractive index becomes successively higher from the outer surface side to the semiconductor substrate side. Due to this, the antireflection effect is greatly improved compared with an ordinary single layer silicon nitride film and simultaneously a defect reducing effect not obtainable with the conventional TiO₂, ZnS, etc. is obtained. As a secondary effect, it is possible to form various component layers by addition of ingredients or control of the bond form of the silicon nitride film, so it is possible to reduce the production costs by simplification of the production process compared with the conventional layer configuration having TiO₂, ZnS, or other different materials as component layers.

In the second aspect of the invention, the refractive indices of the component layers forming the stacked structure silicon nitride film can be adjusted by any of the content of hydrogen or a halogen, the ratio of Si content/N content, and the N—H/Si—H bond ratio.

Further, in the second aspect of the invention, if interposing a region corresponding to a boundary region defined in any of the first, second, and third embodiments of the first aspect of the invention inside the component layer adjoining the semiconductor substrate in the component layers of the silicon nitride film, it is possible to further raise the defect reducing effect of the substrate surface.

### EXAMPLE 1

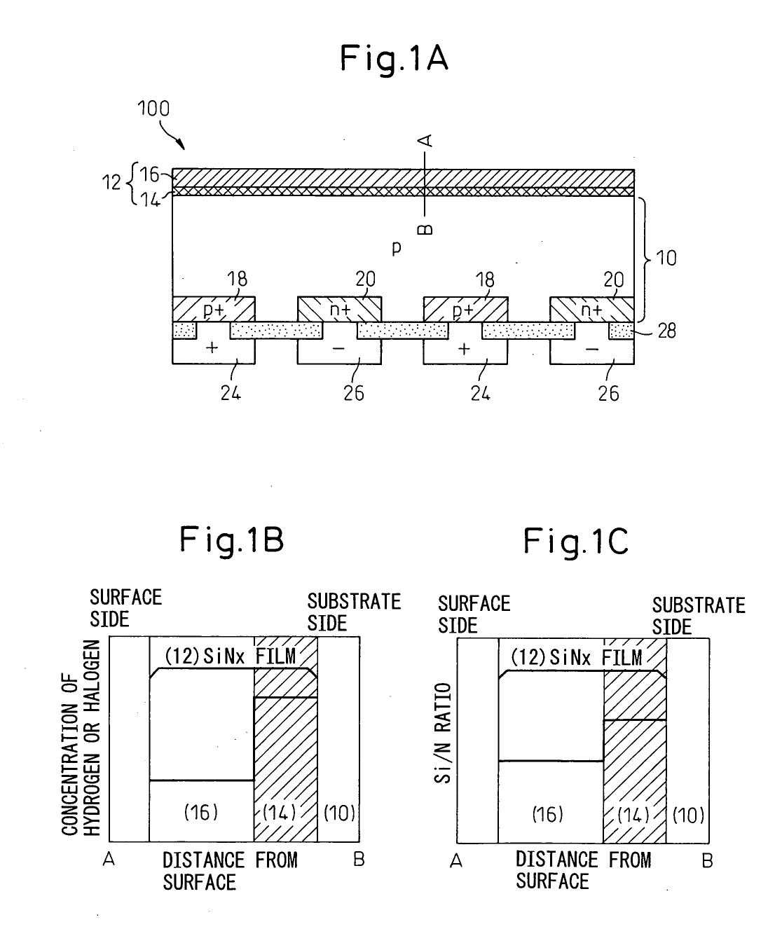

FIGS. 1A to 1C show an example of a photovoltaic converter according to the first embodiment of the first aspect of the invention. FIG. 1A is a cross-sectional view of the photovoltaic converter, FIG. 1B shows the profile of concentration of hydrogen or a halogen along line A-B of the same, and FIG. 1C shows the profile of the Si concentration/N concentration ratio.

As shown in FIG. 1A, the photovoltaic converter 100 of the present invention is formed on a p-type semiconductor substrate 10 and is provided on its light receiving surface (top surface in figure) with a protective film/antireflection film 12 made of silicon nitride. The back surface side end (bottom end in the figure) of the semiconductor substrate 10 is formed with a p+ layer 18 and n+ layer 20 as carrier diffusion layers by diffusion. These are connected to the positive and negative outside output electrodes 24 and 26. The back surface at other than the connection positions of the carrier polarization layers 18 and 20 and the output electrodes 24 and 26 are covered by a protective film (insulating film) 28.

As a characterizing feature of the present embodiment, as shown in FIG. 1B, the silicon nitride film 12 is increased in the content of hydrogen or a halogen over the other portions 16 at the boundary region 14 with the semiconductor substrate 10. The surface of the semiconductor substrate 10 is reduced in dangling bonds by bonding with hydrogen or a halogen. As a result, surface defects serving as recombination sites of the carrier are decreased and the power generation efficiency is improved by reduction of the carrier recombination loss.

However, if the concentration of hydrogen or a halogen becomes higher, the refractive index of the silicon nitride film 12 will fall at the boundary region 13 and the antireflection effect will end up falling.

Therefore, in the present embodiment, as shown in FIG. 1C, at the boundary region 14, the ratio of the Si content/N content is increased compared with the other portions 16. Due to this, the refractive index of the silicon nitride film 12 at the boundary region 14 is increased, the drop in refractive index due to the increase in hydrogen or a halogen is cancelled out, and therefore the index is kept equal to the other portions 16. As a result, the silicon nitride film 12 is kept constant in refractive index as a whole and a good antireflection effect can be secured.

Further, the protective function of the silicon nitride film 12 is secured by the portions 16 other than the boundary region 14.

In this way, according to the present embodiment, a photovoltaic converter 100 maintained in protective function of the silicon nitride film 12, simultaneously reduced in the reflection loss and carrier recombination loss, and improved in the power generation efficiency is obtained.

A specific example of the material forming the photovoltaic converter 100 of this example is shown below:
<Silicon nitride film 12>
Overall thickness: 100 nm
Thickness of boundary region 14: 30 nm
Composition of portion 16 other than boundary region
   Si: 39% (34 to 44%)
   N: 51% (46 to 56%)
   H: 10% (5 to 15%)
Composition of boundary region 14 (*)
   Si: 41% (36 to 46%)
   N: 41% (36 to 46%)
   H: 18% (13 to 23%)
      *: Unparenthesized figures: present example, parenthesized figures: generally possible range
<Semiconductor Substrate 10>
Substrate material: Crystalline Ge
Thickness: 200 nm
<Back surface carrier polarization layers: p+ layer 18, n+ layer 20>
Back surface carrier concentration: 1×10¹⁹ cm⁻³
Diffusion depth: 1.5 μm

<Back surface protective film 28>
Material: Silicon nitride film
Thickness: 300 nm
<Electrodes 24 and 26>
Material: Al (also Ag, Ti, Cu, Ni, Cr, or another ordinary electrode material possible)

### EXAMPLE 2

In Example 1, the content of hydrogen or a halogen (means X) and the ratio of the Si content/N content (means Y) were made constant profiles over the entire region of the boundary region 14, but the invention is not particularly limited to this. The means X and the means Y should be combined so that the refractive index inside the boundary region 14 is maintained equal to the other portions 16 (constant over entire boundary region 14). That is, the two means should balanced or combined so that the change in the refractive index due to the means X and the change in the refractive index due to the means Y cancel each other out to give a substantially zero change.

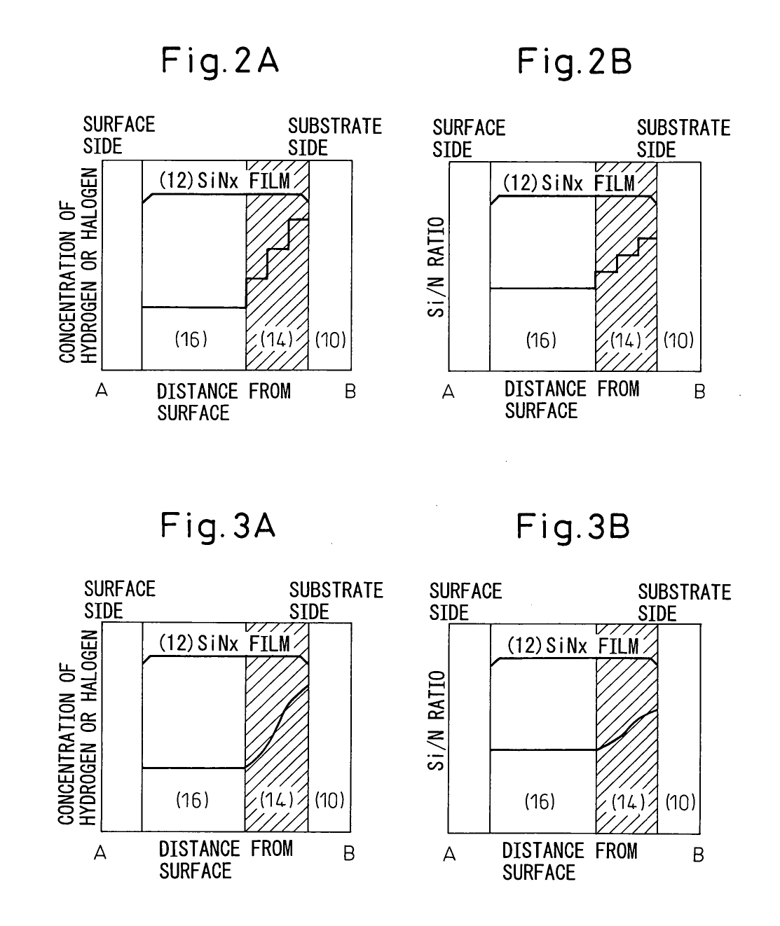

FIGS. 2A and 2B show preferable examples of profiles. The profiles increase stepwise from the surface side to the substrate 10 side in accordance with the content of hydrogen or a halogen (means X) in FIG. 2A and the ratio of the Si content/N content (means Y) in FIG. 2B. Due to this, the internal stress in the silicon nitride film 12 caused by change of the composition is reduced, so (a) peeling of the silicon nitride film 12 due to the heat treatment in the device fabrication process is prevented and simultaneously (b) defects at the surface of the substrate 10 contiguous with the silicon nitride film 12 are reduced.

As a result, the production yield is improved by the prevention of peeling of the silicon nitride film 12, the production costs are reduced, carrier recombination loss is further reduced by reduction of the surface defects of the substrate 10, and the power generation efficiency is further improved.

A specific example of the material configuration in the case of application of the profiles of FIGS. 2A and 2B to the photovoltaic converter 100 is shown below:

<Silicon nitride film 12>
Overall thickness: 100 nm
Thickness of boundary region 14: 30 nm
Composition of portion 16 other than boundary region
   Si: 39% (34 to 44%)
   N: 51% (46 to 56%)
   H: 10% (5 to 15%)
Composition of boundary region 14 (*)
   First layer (surface side: near A in the figure)
      Si: 40% (35 to 45%)
      N: 47% (42 to 52%)
      H: 13% (8 to 18%)
   Second layer
      Si: 41% (36 to 46%)
      N: 43% (38 to 48%)
      H: 16% (11 to 21%)
   Third layer (substrate side: near B in the figure)
      Si: 41% (36 to 46%)
      N: 40% (35 to 45%)
      H: 19% (14 to 24%)
         *: Unparenthesized figures: present example, parenthesized figures: generally possible range

The semiconductor substrate 10, the back surface carrier polarization layer (p+ layer 18, n+ layer 20), the back surface protective film 28, and the electrodes 24 and 26 may be the same as in Example 1.

### EXAMPLE 3

In this example, as shown in FIGS. 3A and 3B, the content of the hydrogen or a halogen (means X) (FIG. 3A) and the ratio of the Si content/N content (means Y) (FIG. 3B) are continuously increased from the surface side (A side) to the substrate side (B side) in profile.

By adopting this continuous increase profile, the effect of change due to the step-wise increase profile of Example 2 is further enhanced. That is, the internal stress of the silicon nitride film 12 is further reduced so that (a) the effect of prevention of peeling of the silicon nitride film 12 due to the heat treatment in the device fabrication process is further enhanced and simultaneously (b) the effect of reduction of defects at the surface of the substrate 10 contiguous with the silicon nitride film 12 is further enhanced.

As a result, (a) the improvement in the production yield due to the prevention of peeling of the silicon nitride film 12 and the reduction in the production costs due to the same become more remarkable and (b) the reduction in the carrier recombination loss due to reduction of the surface defects of the substrate 10 and the improvement of the power generation efficiency due to the same become further remarkable.

A specific example of the material configuration in the case of application of the profiles of FIGS. 3A and 3B to the photovoltaic converter 100 is shown below:
<Silicon nitride film 12>
Overall thickness: 100 nm
Thickness of boundary region 14: 30 nm
Composition of portion 16 other than boundary region
   Si: 39% (34 to 44%)
   N: 51% (46 to 56%)
   H: 10% (5 to 15%)
Composition of boundary region 14 (*)
   Si: Continuous increase from 39% (34 to 44%) of surface side (A side) to 41% (36 to 46%) of substrate side (B side).
   N: Continuous increase from 51% (46 to 56%) of surface side (A side) to 40% (35 to 45%) of substrate side (B side).
   H: Continuous increase from 10% (5 to 15%) of surface side (A side) to 19% (14 to 24%) of substrate side (B side).
      *: Unparenthesized figures: present example, parenthesized figures: generally possible range

The semiconductor substrate 10, the back surface carrier polarization layer (p+ layer 18, n+ layer 20), the back surface protective film 28, and the electrodes 24 and 26 may be the same as in Example 1.

### EXAMPLE 4

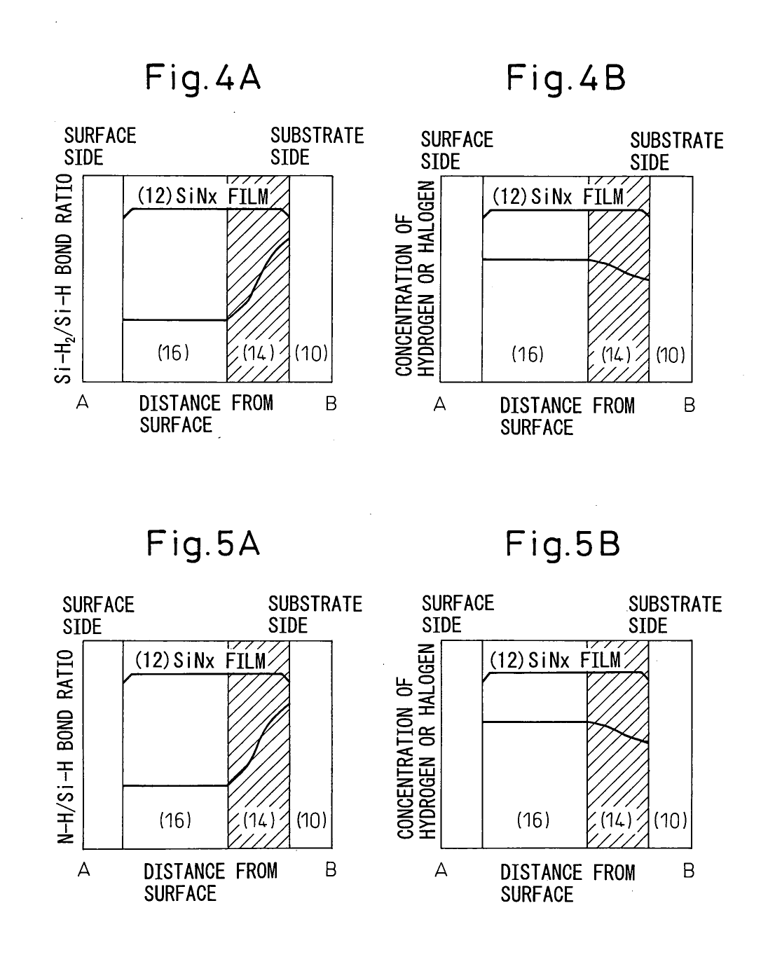

FIGS. 4A and 4B show characterizing features of the boundary region of a photovoltaic converter according to a second embodiment of the first aspect of the invention. The cross-sectional structure is similar to the structure of Example 1 shown in FIGS. 1A to 1C. Only the contents of the means X and Y applied to the boundary region differ. In the following explanation, see the parts of the photovoltaic converter shown in FIGS. 1A and 1B.

That is, the characterizing feature of the present example, as shown in FIG. 4A, is that the silicon nitride film 12 is increased in S₁—H₂/Si—H bond ratio at the boundary region 14 with the semiconductor substrate 10 compared with the other portions 16 (means X). Due to this, the surface of the semiconductor substrate 10 is reduced in surface defects serving as recombination sites of carriers, reduced in carrier recombination loss, and improved in power generation efficiency.

However, if the S₁—H₂/Si—H bond ratio is increased, the refractive index of the silicon nitride film 12 falls at the boundary region 14 and the antireflection effect ends up falling.

Therefore, in this example, as shown in FIG. 4B, at the boundary region 14, the content of hydrogen or a halogen is decreased compared with the other portions 16 (means Y). Due to this, the refractive index of the silicon nitride film 12 at the boundary region 14 is increased, and the drop in refractive index due to the increase in S₁—H₂/Si—H bond ratio is cancelled out to maintain the index equal to the other portions 16. As a result, the silicon nitride film 12 is maintained constant in refractive index overall and a good antireflection effect can be secured.

Note that in this example, as the refractive index increasing means Y for canceling out the drop in refractive index due to the defect reducing means X, the content of hydrogen or a halogen was reduced, but similar actions and effects can be obtained even if increasing the ratio of the Si content/N content as the means Y.

In this example as well, the protective function of the silicon nitride film 12 is secured by the portions 16 other than the boundary region 14.

In this way, according to this example, a photovoltaic converter maintained in protective function of the silicon nitride film 12, simultaneously reduced in the reflection loss and carrier recombination loss, and improved in the power generation efficiency is obtained.

A specific example of the material forming the photovoltaic converter of this example is shown below:
<Silicon nitride film 12>
Overall thickness: 100 nm
Thickness of boundary region 14: 30 nm
Composition of portion 16 other than boundary region
   Si: 36% (31 to 41%)
   N: 49% (46 to 56%)
   H: 15% (10 to 20%)
   Si—H2/Si—H bond region: 0.7 (0.2 to 1.2)
Composition of boundary region 14 (*)
   Si—H2/Si—H bond ratio: Continuous increase from 0.7% (0.2 to 1.2%) of surface side (A side) to 1.4% (0.9 to 1.9%) of substrate side (B side).
   H: Continuous increase from 15% (10 to 20%) of surface side (A side) to 12% (7 to 17%) of substrate side (B side).
      *: Unparenthesized figures: present example, parenthesized figures: generally possible range

The semiconductor substrate 10, the back surface carrier polarization layer (p+ layer 18, n+ layer 20), the back surface protective film 28, and the electrodes 24 and 26 may be the same as in Example 1.

Note that in this example, the profile was made one of a continuous increase and decrease as shown in FIGS. 4A and 4B, but it is also possible to use a profile constant over the entire boundary region 14 as shown in Example 1 (FIGS. 1A and 1BA) or a profile of a stepwise increase and decrease as in Example 2 (FIGS. 2A and 2B).

### EXAMPLE 5

FIGS. 5A and 5B show characterizing features of the boundary region of a photovoltaic converter according to a third embodiment of the first aspect of the invention. The cross-sectional structure is similar to the structure of Example 1 shown in FIGS. 1A to 1C. Only the contents of the means X and Y applied to the boundary region differ. In the following explanation, see the parts of the photovoltaic converter shown in FIGS. 1A and 1B.

That is, the characterizing feature of the present example, as shown in FIG. 5A, is that the silicon nitride film 12 is increased in N—H/Si—H bond ratio at the boundary region 14 with the semiconductor substrate 10 compared with the other portions 16 (means X). Due to this, the surface of the semiconductor substrate 10 is reduced in surface defects serving as recombination sites of carriers, reduced in carrier recombination loss, and improved in power generation efficiency.

However, if the N—H/Si—H bond ratio is increased, the refractive index of the silicon nitride film 12 falls at the boundary region 14, and the antireflection effect ends up falling.

Therefore, in this example, as shown in FIG. 5B, at the boundary region 14, the content of hydrogen or a halogen is decreased compared with the other portions 16 (means Y). Due to this, the refractive index of the silicon nitride film 12 at the boundary region 14 is increased, and the drop in refractive index due to the increase in N—H/Si—H bond ratio is cancelled out to maintain the index equal to the other portions 16. As a result, the silicon nitride film 12 is maintained constant in refractive index overall and a good antireflection effect can be secured.

Note that in this example, as the refractive index increasing means Y for canceling out the drop in refractive index due to the defect reducing means X, the content of hydrogen or a halogen was reduced, but similar actions and effects can be obtained even if increasing the ratio of the Si content/N content as the means Y.

In this example as well, the protective function of the silicon nitride film 12 is secured by the portions 16 other than the boundary region 14.

In this way, according to this example, a photovoltaic converter maintained in protective function of the silicon nitride film 12, simultaneously reduced in the reflection loss and carrier recombination loss, and improved in the power generation efficiency is obtained.

A specific example of the material forming the photovoltaic converter of this example is shown below:
<Silicon nitride film 12>
Overall thickness: 100 nm
Thickness of boundary region 14: 30 nm
Composition of portion 16 other than boundary region
   Si: 36% (31 to 41%)
   N: 49% (46 to 56%)
   H: 15% (10 to 20%)
   N—H/Si—H bond ratio: 0.5 (0.2 to 0.8)
Composition of boundary region 14
   N—H/Si—H bond ratio: Continuous increase from 0.5 (0.2 to 0.8) of surface side (A side) to 1.0 (0.7 to 1.3) of substrate side (B side)
   H: Continuous decrease from 15% (10 to 20%) of surface side (A side) to 12% (7 to 17%) of substrate side (B side)
      *: Unparenthesized figures: present example, parenthesized figures: generally possible range

The semiconductor substrate 10, the back surface carrier polarization layer (p+ layer 18, n+ layer 20), the back surface protective film 28, and the electrodes 24 and 26 may be the same as in Example 1.

Note that in this example, the profile was made one of a continuous increase and decrease as shown in FIGS. 5A and 5B, but it is also possible to use a profile constant over the entire boundary region 14 as shown in Example 1 (FIGS. 1A and 1BA) or a profile of a stepwise increase and decrease as in Example 2 (FIGS. 2A and 2B).

### EXAMPLE 6

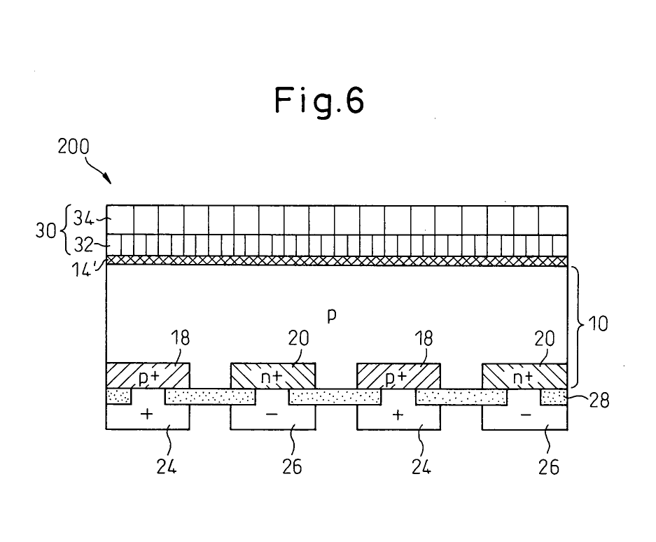

FIG. 6 shows an example of a photovoltaic converter according to a fourth embodiment of the first aspect of the invention by a cross-sectional view.

The photovoltaic converter 200 of this example is characterized by being provided at its light receiving surface with an antireflection film (optical thin film) 30 comprised of a material other than silicon nitride and by having a silicon nitride film 14′ corresponding to a boundary region 14 of any of Examples 1 to 5 interposed between the antireflection film 30 and semiconductor substrate 10. Other than this, the structure is similar to the photovoltaic converter 100 of Example 1 shown in FIG. 1A. The corresponding parts are shown by the same reference numerals.

The antireflection film 30 is a two-layer structure comprised of for example a lower layer of a high refractive index film 32 and an upper layer of a low refractive index film 34. Due to this, a high antireflection effect can be obtained. This is an example of an antireflection film used in the past.

The characterizing feature of this example is the interposition of the silicon nitride film 14′ between the antireflection film 30 and the substrate 10. Due to the silicon nitride film 14′, the surface defects of the semiconductor substrate 10 are reduced and the carrier recombination loss is reduced. The refractive index of the silicon nitride film 14′ can be adjusted to be equal to the high refractive index film 32 by any of the methods of Examples 1 to 5 and the antireflection effect can be maintained.

A specific example of the material forming the photovoltaic converter 200 of this example is shown below:
<Antireflection film (optical thin film) 30>
Low refractive index film 34: SiO₂, 210 nm thick
High refractive index film 32: TiO₂, 120 nm thick
<Silicon nitride film 14′>
Thickness: 10 nm

The semiconductor substrate 10, the back surface carrier polarization layer (p+ layer 18, n+ layer 20), the back surface protective film 28, and the electrodes 24 and 26 may be the same as in Example 1.

### EXAMPLE 7

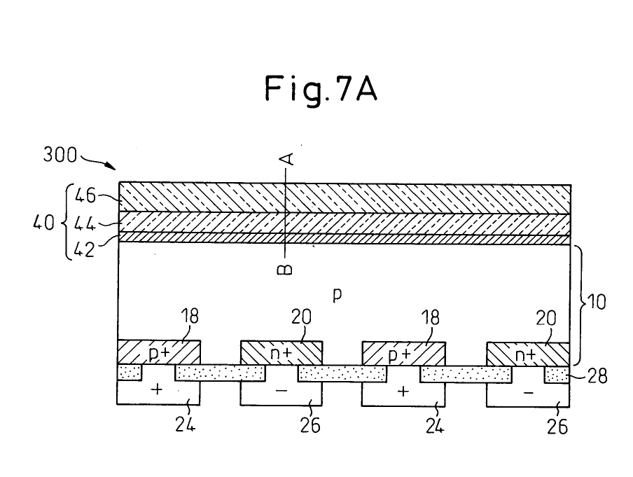

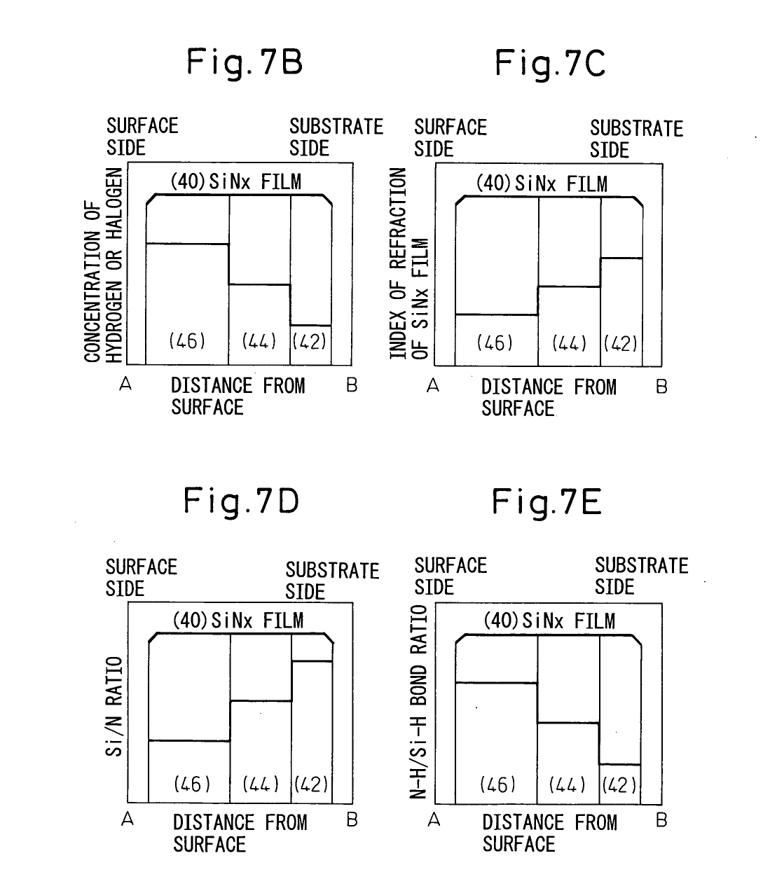

FIG. 7A is a cross-sectional view of a photovoltaic converter according to a first embodiment of the second aspect of the invention. The illustrated photovoltaic converter 300 is characterized by being provided with, at the light receiving surface, a silicon nitride film 40 as the protective film/antireflection film. The silicon nitride film 40 is comprised of a high refractive index layer 42, medium refractive index layer 44, and low refractive index layer 46 successively stacked together. The rest of the configuration is similar to that of the photovoltaic converter 100 of Example 1 shown in FIG. 1A. Corresponding parts are assigned the same reference numerals.

By forming the protective film/antireflection film 40 in this way, the surface defects of the semiconductor substrate 10 are reduced, so carrier recombination loss can be reduced. Simultaneously, the refractive index becomes higher in the order of the component layers 46->44->42 from the outer surface side (A side) to the semiconductor substrate side (B side), so the reflection loss can be reduced.

The means for adjusting the refractive index of the silicon nitride film to various levels in this way will be explained next.

Refractive Index Adjusting Means 1

As one means, as shown in FIG. 7B, by making the content of hydrogen or a halogen successively lower from high to medium to low from the surface side (A side), as shown in FIG. 7C, it is possible to make the refractive index successively higher from low to medium to high.

An example of the material configuration of the layers in this case is shown below:
<Silicon nitride film 40>
Upper layer 46: hydrogen content of 27%, refractive index of 1.50, and thickness of 133 nm
Medium layer 44: hydrogen content of 12%, refractive index of 2.00, and thickness of 100 nm
Lower layer 42: hydrogen content of 5%, refractive index of 2.65, and thickness of 75.5 nm

The semiconductor substrate 10, the back surface carrier polarization layer (p+ layer 18, n+ layer 20), the back surface protective film 28, and the electrodes 24 and 26 may be the same as in Example 1.

Refractive Index Adjusting Means 2

Further, as another means, as shown in FIG. 7E, by making the N—H bond/Si—H bond ratio successively lower from high to medium to low from the surface side (A side), as shown in FIG. 7C, it is possible to make the refractive index successively higher from low to medium to high.

An example of the material configuration of the layers in this case is shown below:
<Silicon nitride film 40>
Upper layer 46: Si/N content ratio of 0.5, refractive index of 1.50, and thickness of 133 nm
Medium layer 44: Si/N content ratio of 0.8, refractive index of 2.00, and thickness of 100 nm
Lower layer 42: Si/N content ratio of 1.2, refractive index of 2.65, and thickness of 75.5 nm

The semiconductor substrate 10, the back surface carrier polarization layer (p+ layer 18, n+ layer 20), the back surface protective film 28, and the electrodes 24 and 26 may be the same as in Example 1.

Refractive Index Adjusting Means 3

As another means, as shown in FIG. 7D, by making the ratio of the Si content/N content successively higher from low to medium to high from the surface side (A side), as shown in FIG. 7C, it is possible to make the refractive index successively higher from low to medium to high.

An example of the material configuration of the layers in this case is shown below:
<Silicon nitride film 40>
Upper layer 46: N—H/Si—H bond ratio of 2.0, refractive index of 1.50, and thickness of 133 nm
Medium layer 44: N—H/Si—H bond ratio of 1.3, refractive index of 2.00, and thickness of 100 nm
Lower layer 42: N—H/Si—H bond ratio of 0.6, refractive index of 2.65, and thickness of 75.5 nm

The semiconductor substrate 10, the back surface carrier polarization layer (p+ layer 18, n+ layer 20), the back surface protective film 28, and the electrodes 24 and 26 may be the same as in Example 1.

As explained above, according to the present invention, by using a silicon nitride film as an antireflection film without using an SiO₂, TiO₂, ZnS, or other optical thin film, an antireflection effect can be secured while enjoying the defect reducing effect by the silicon nitride film.

### EXAMPLE 8

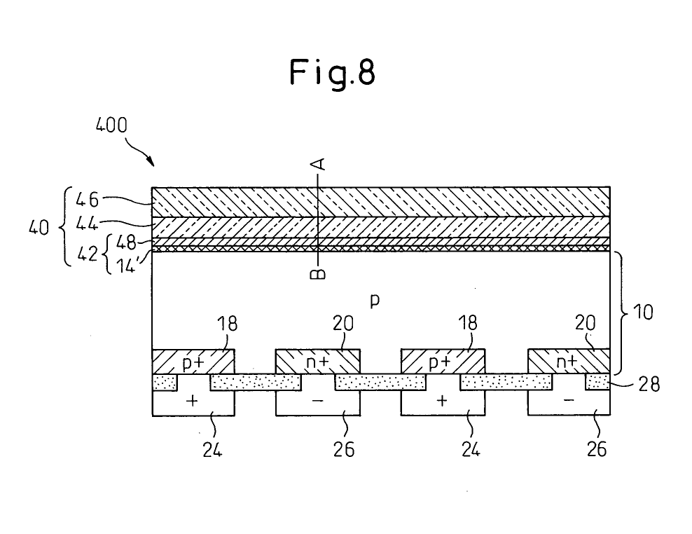

FIG. 8 shows an example of a photovoltaic converter according to a second embodiment of the second aspect of the invention by a cross-sectional view.

The photovoltaic converter 400 of this example is characterized by being provided at its light receiving surface with a silicon nitride film 40 (46/44/42) of Example 7 as an antireflection film and by the bottom layer (high refractive index layer) 42 in the silicon nitride film 40 being comprised of a boundary region 14′ corresponding to a boundary region 14 of any of Examples 1 to 5 and other portions 48. The rest of the configuration is similar to the photovoltaic converter 100 of Example 1 shown in FIG. 1A. Corresponding parts are shown by the same reference numerals.

According to the present example, due to the boundary region 14′, the surface defect of the semiconductor substrate 10 is decreased and the carrier recombination loss is reduced. The refractive index of the boundary region 14′ can be adjusted to be equal to the other portions 48 by any of the methods explained in Examples 1 to 5 and therefore the antireflection effect can be maintained.

A specific example of the material forming the photovoltaic converter 400 of this example is shown below:
<Silicon nitride film 42>
Portion 48 other than boundary region
   Si: 49%
   N: 41%
   H: 10%
Boundary region 14′
   Si: 49%
   N: 33%
   H: 18%

The other parts may be the same as in Example 7.

The method of formation of the silicon nitride film 12 (14, 16), 14′, 40 (42 (14′, 48), 44, 46) in Examples 1 to 8 explained above will be explained next.

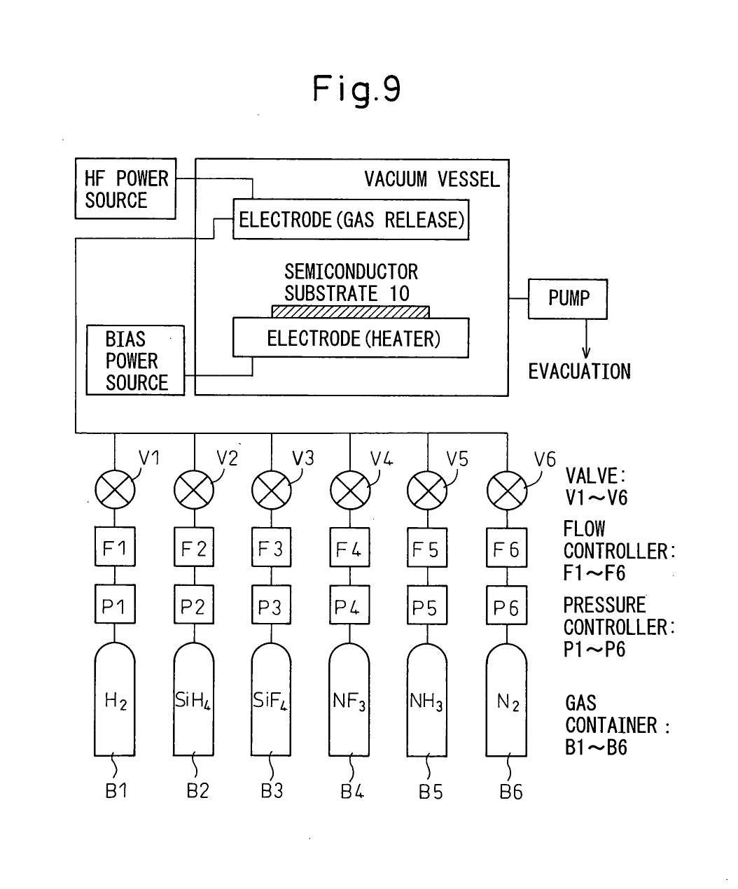

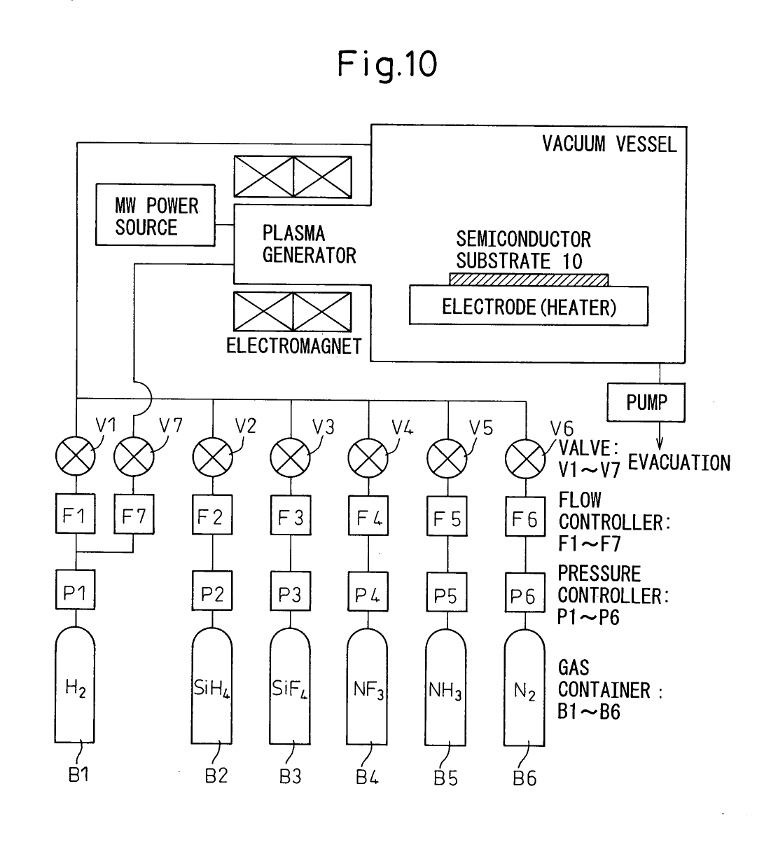

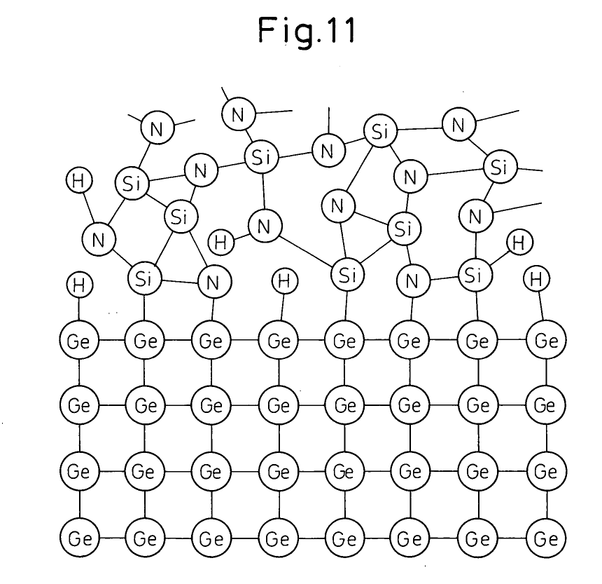

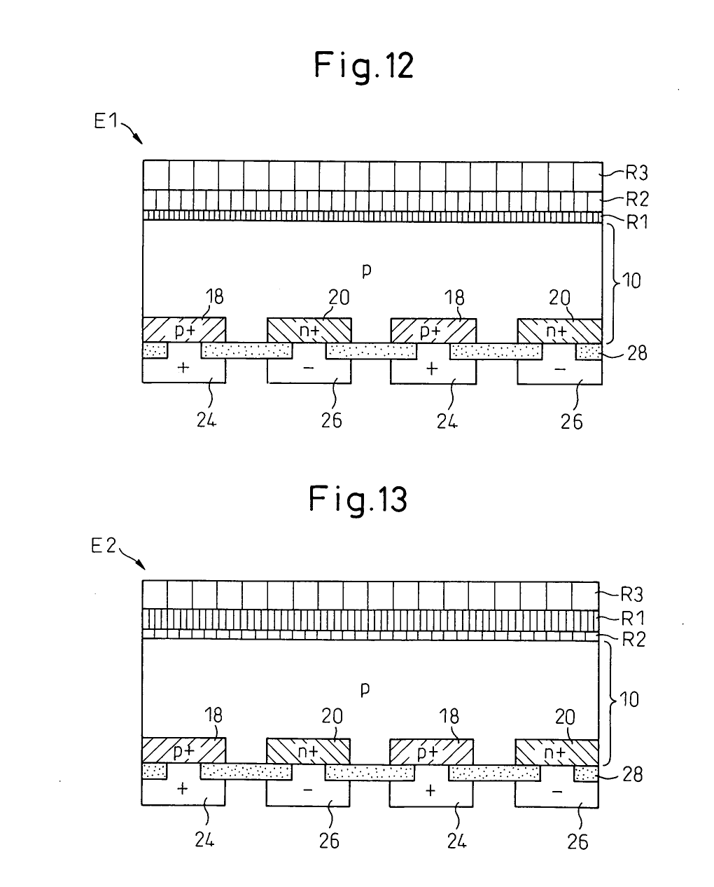

The silicon nitride film may be formed using a plasma CVD system shown in FIG. 9 or an ECR plasma CVD system shown in FIG. 10.

Each system is provided with gas tanks V1 to V6 for H₂, SiH₄, SiF₄, NF₃, NH₃, and N₂ as the materials for the Si, N, H, and halogen for forming the silicon nitride film. The amounts of gases are adjusted for each of the material gases by the pressure regulators P1 to P6 and the flow regulators F1 to F6 (F7) and are supplied from the gas release part (not shown) provided at the electrode to the inside of the vacuum container.

In the case of the plasma CVD system of FIG. 9, a pair of electrodes is provided separated by the space forming the gas decomposition section in the vacuum container. A semiconductor substrate 10 is placed at one heater type electrode. Further, in the case of the ECR plasma CVD system of FIG. 10, the vacuum container is provided with a plasma generator igniting a magnetic field. The semiconductor substrate 10 is placed at a portion separate from the plasma generator.

The inside of the container is reduced in pressure by a pump to adjust the pressure. A high frequency power source is used for electrodischarge to break down and activate the gas.

Due to this, the substrate 10 is formed with a silicon nitride film.

At this time, by adjusting the ratio of gas ingredients, pressure, substrate temperature, high frequency power, bias power, etc., the target element concentration and distribution of bonding ratio is realized in the silicon nitride film.

As one example, the basic conditions for formation of the silicon nitride film are as follows:
Gas used (flow rate ratio): SiH₄ (10%), NH₃ (5%), N₂ (85%)
Substrate temperature: 300° C.
Pressure: 80 Pa
High frequency power source: frequency 13.56 MHz, power density (with respect to electrode area): 0.2 W/cm²

Summarizing the effects of the invention, according to the present invention, it is possible to provide a photovoltaic converter maintaining the function of a protective film, simultaneously reducing the reflection loss and carrier recombination loss, and raising the power generation efficiency.

While the invention has been described with reference to specific embodiments chosen for purpose of illustration, it should be apparent that numerous modifications could be made thereto by those skilled in the art without departing from the basic concept and scope of the invention.

1. A photovoltaic converter formed on a semiconductor substrate and provided on its light receiving surface with a silicon nitride film as a protective film/antireflection film, wherein
a content of hydrogen or a halogen is increased and a ratio of Si content/N content is increased at a boundary region of the silicon nitride film with the semiconductor substrate compared with other portions so as to maintain a refractive index at said boundary region equal to the other portions.

2. A photovoltaic converter as set forth in claim 1, wherein said increase is a step-wise or continuous gradual increase from a silicon nitride film body side to the semiconductor substrate side.

3. A photovoltaic converter formed on a semiconductor substrate and provided on its light receiving surface with a silicon nitride film as a protective film/antireflection film, wherein
an S₁—H₂/Si—H bond ratio is increased and a content of hydrogen or a halogen is decreased or a ratio of Si content/N content is increased at a boundary region of the silicon nitride film with the semiconductor substrate compared with other portions so as to maintain a refractive index at said boundary region equal to the other portions.

4. A photovoltaic converter as set forth in claim 3, wherein said increase and decrease are a step-wise or continuous gradual increase and gradual decrease from a silicon nitride film body side to the semiconductor substrate side.

5. A photovoltaic converter formed on a semiconductor substrate and provided on its light receiving surface with a silicon nitride film as a protective film/antireflection film, wherein
an N—H/Si—H bond ratio is increased and a content of hydrogen or a halogen is reduced or a ratio of Si content/N content is increased at a boundary region of the silicon nitride film with the semiconductor substrate compared with other portions so as to maintain a refractive index at said boundary region equal to the other portions.

6. A photovoltaic converter as set forth in claim 5, wherein said increase and decrease are a step-wise or continuous gradual increase and gradual decrease from a silicon nitride film body side to the semiconductor substrate side.

7. A photovoltaic converter formed on a semiconductor substrate and provided on its light receiving surface with an antireflection film comprised of a material other than silicon nitride, wherein
a silicon nitride film of a composition and bond form corresponding to a boundary region as set forth in any one of claims 1 to 6 is interposed between the antireflection film and semiconductor substrate.

8. A photovoltaic converter formed on a semiconductor substrate and provided on its light receiving surface with a silicon nitride film as a protective film/antireflection film, wherein
said silicon nitride film is comprised of a plurality of component layers stacked together and the refractive indices of the component layers increase from the outer surface side to the substrate side.

9. A photovoltaic converter as set forth in claim 8, wherein the refractive indices of the component layers are adjusted by one of the content of hydrogen or a halogen, ratio of Si content/N content, and N—H/Si—H bond ratio.

10. A photovoltaic converter as set forth in claim 8, wherein a region corresponding to the boundary region as set forth in any one of claims 1 to 6 is interposed inside one of the component layers of the silicon nitride film that adjoins the semiconductor substrate.

11. A photovoltaic converter as set forth in claim 9, wherein a region corresponding to the boundary region as set forth in any one of claims 1 to 6 is interposed inside one of the component layers of the silicon nitride film that adjoins the semiconductor substrate.
